(19) United States
(12) Patent Application Publication
(10) Pub. No.: US 2002/0005563 A1
(43) Pub. Date: Jan. 17, 2002

(54) Fuse structure and application thereof for a CMOS sensor

(76) Inventor: Tzi-Hsiung Shu, San Jose, CA (US)

Correspondence Address: J.C. PATENTS INC., 4 Venture, Suite 250, Irvine, CA, 92618, US

(21) Appl. No.: 09/838,400

(22) Filed: Apr. 19, 2001

Related U.S. Application Data
(60) Provisional application No. 60/217,540, filed on Jul. 12, 2000.

(51) Int. Cl. H01L 29/00; H01L 27/10

(52) U.S. Cl. 257/529; 257/209

(57) ABSTRACT

The invention provides a simple fuse structure that has been implemented using the existing standard CMOS process layers without adding to the process complexity. The fuse is applied as an integrated on-chip memory element in the CMOS image sensor circuit to record the address information of the bad pixels. The application of integrated memory element on the same chip eliminates the need for external memory and therefore reduces the cost and overall component count of the camera module. The dynamic readout circuit of the fuse array reduces the data delay and increases the operating frequency of the circuit. In a process that has multiple layers of passivation, there can be a thin layer of passivation layer on top of the fuse to prevent oxidation and moisture penetration. Dividing the memory array into separate banks separated by the tri-state drivers has the advantage of reducing the parasitic capacitance that the memory element has to drive, therefore reducing the rise/fall time and effectively increases the readout speed. The idea can be readily applied to more than two levels of division. Although a dedicated layer can be designed into process flow to form the fuse, the preferred structure is to use the existing process layers as the fuse material in order to reduce cost. The most commonly used fuse materials are poly-silicon layer and metal layer. The fuse can be cut open by electrical means such as an electrical pulse, or by laser. Fuses of poly-silicon or metal composition, or variations of such, can be used as the memory element in any of the existing standard CMOS process for use in the CMOS image sensor application to record the appropriate information. Such information includes, but not limited to the bad pixel addresses for use later on to correct the bad pixel outputs.

### CROSS-REFERENCE TO RELATED APPLICATION

This application claims the priority benefit of U.S.A. provisional application Ser. No. 60/217,540, filed Jul. 12, 2000.

### BACKGROUND OF THE INVENTION

1. Field of Invention

The present invention relates to a CMOS sensor, and more particularly, to a CMOS image sensor wherein a fuse structure and a dynamic readout circuit are designed and implemented as an integrated part of the CMOS image sensor.

2. Description of Related Art

Digital image capture devices typically include an imaging device which is controlled by a computer system which accesses raw image data captured by the imaging device and then processes and compresses the data before storing the compressed data into a memory. The conventional device captures raw image data and then remains unusable until the data is completely processed and stored into flash memory.

In processing image data, typical digital image capture devices operate with exclusive and specific image processing. Thus, all the potential manipulations on image data, such as linearization, sharpening, and compression, occur as a result of isolated preset programming and/or specifically designed hardware.

While some level of manipulation of image data is achieved with the programming or hardware, attempts to alter and improve the processing are hampered by the rigid structure of using a single file/specific component.

The main circuit block of an image sensor circuit is the image sensor array, consisting of an array of identical sensor pixels, each of which converts the incident light energy into a corresponding electrical signal. A lens or a set of lenses are typically used to project and focus the image from the surrounding scenery onto the sensor array. Because the image projected on the sensor array typically contain different variations in light intensity and color spectrum, each sensor pixel in the array produces different output signals depending on the particular portion of the image that is projected onto that pixel. The electrical outputs from the pixels are sensed, or read out, in a predetermine sequence. Based on the data readout from the pixels and the sequence of signal readout, one can reconstruct the image that is projected onto the sensor array. The output data from each pixel in the sensor array contributes to the overall reconstructed image.

However, if one or more pixels produce erratic output signals that do not correspond to the individual incident light, the reconstructed image can suffer degradation in image quality. The pixels that produce erratic output signals are considered bad pixels. One example of a bad pixel is a “dead” pixel, which produces a zero signal regardless of the incident light condition. Another example of a bad pixel is a “hot” pixel, which produces a high output signal even if there is no incident light. A dead pixel causes a black dot on the reconstructed image, while a hot pixel causes a bright dot on the reconstructed image. Since a bad pixel cannot respond to the incident light in a pre-determined way, the image data corresponding to the bad pixel output is therefore not available.

Therefore, a need exists for an improved fuse structure and a dynamic readout circuit which are designed and implemented as an integrated part of the CMOS image sensor in standard CMOS process, wherein the fuse is applied as an integrated on-chip memory element in the CMOS image sensor circuit to record the address information of bad pixels. In this way, image correction can be performed on pixels recorded as bad.

### SUMMARY OF THE INVENTION

To achieve these and other advantages and in order to overcome the disadvantages of the conventional image sensor in accordance with the purpose of the invention as embodied and broadly described herein, the present invention provides a fuse structure and application thereof for a CMOS sensor that implements a fuse structure and a dynamic readout circuit which are designed as an integrated part of the CMOS image sensor in standard CMOS process.

The main circuit block of an image sensor circuit is the image sensor array, consisting of an array of identical sensor pixels, each of which converts the incident light energy into a corresponding electrical signal. A lens or a set of lenses are typically used to project and focus the image from the surrounding scenery onto the sensor array. Because the image projected on the sensor array typically contain different variations in light intensity and color spectrum, each sensor pixel in the array produces different output signals depending on the particular portion of the image that is projected onto that pixel. The electrical outputs from the pixels are sensed, or read out, in a pre-determine sequence. Based on the data readout from the pixels and the sequence of signal readout, one can reconstruct the image that is projected onto the sensor array. The output data from each pixel in the sensor array contributes to the overall reconstructed image.

However, if one or more pixels produce erratic output signals that do not correspond to the individual incident light, the reconstructed image can suffer degradation in image quality. The pixels that produce erratic output signals are considered bad pixels. One example of a bad pixel is a “dead” pixel, which produces a zero signal regardless of the incident light condition. Another example of a bad pixel is a “hot” pixel, which produces a high output signal even if there is no incident light. A dead pixel causes a black dot on the reconstructed image, while a hot pixel causes a bright dot on the reconstructed image. Since a bad pixel cannot respond to the incident light in a pre-determined way, the image data corresponding to the bad pixel output is therefore not available.

When a sensor array is built in any integrated circuit process, due to a variety of defect mechanisms there is a finite probability that any given pixel can be bad. As a result, the probability of finding a sensor array containing no bad pixel decreases rapidly as the sensor array size increases.

However, if the output data from the bad pixel can be corrected to a certain degree, even though not fully corrected, it can be deemed useful enough not to reject the sensor, thus increasing the yield rate of the process.

There are many methods of performing the correction, the simplest one being a linear interpolation between the neighboring pixel outputs. On the other hand, before any correction can be done it is necessary to know which pixel needs to be corrected, which requires some kind of memory element to record the coordinates, or addresses, of the bad pixels. External off-chip memories, a ROM, for example can be used to record the addresses. The approach will require an additional memory chip that occupies area on the PC board, increases overall power dissipation, and complicates the system design. An on-chip memory element is therefore desired to eliminate the above problems associated with external memories. Furthermore, it is preferred that the memory element is able to store the bad pixel addresses indefinitely. In most standard CMOS logic process there is no memory element available that can store information indefinitely. A memory element must be created with minimal change to the process flow.

Fuses of poly-silicon or metal composition, or variations of such, can be used as the memory element in any of the existing standard CMOS process for use in the CMOS image sensor application to record the appropriate information. Such information includes, but not limited to the bad pixel addresses for use later on to correct the bad pixel outputs.

The circuit can have one bit output, however, extension of the circuit to multiple bit output is straightforward. The circuit operation is described next.

This embodiment shows the memory array that is composed of m banks of memory elements. Each bank contains n memory elements. Each memory element consists of a fuse and a select pass transistor. The inverters shown (INV₀ to INVₘ₋₁) are tri-state inverters enabled by the enable signal. An address decoder, not shown in the figure, is used to decode the memory address input bits to turn on the proper selection signals (Sel₀ to Selₙ₋₁) and enable signals (en₀ to enₘ₋₁). Only one of the selection signals and one of the enable signals are allowed to turn on. Each memory element therefore has a unique address (i,j), where 0<=i,=m-1 and 0<=j<=n-1. To store the information, the proper fuses must be cut by some means. The data readout operation consists of two phases. The first phase is the precharge phase, during which the precharge signal is turned high to turn on the precharge NMOS transistor. The nodes node₀ through nodeₘ₋₁ therefore precharged to ground. The precharge signal is turned low to turn off the precharge transistors at the end of the precharge phase.

The second phase is the readout phase, during which the proper selection and enable signals are turned on to allow the data stored in the selected memory element to be transmitted to the output. Assuming memory element (i,j) is selected and the fuse in that element is not cut, the node nodei will be allowed to charge up to VDD through the fuse and pass transistor. Since the tri-state inverter INVᵢ is enabled by the decoder output, the output Dₒᵤₜ will be logic 0. If the fuse in the selected memory element is cut, the node nodei will remain low and the output Dₒᵤₜ will be logic 1.

Dividing the memory array into separate banks separated by the tri-state drivers has the advantage of reducing the parasitic capacitance that the memory element has to drive, therefore reducing the rise/fall time and effectively increases the readout speed. The idea can be readily applied to more than two levels of division.

Although a dedicated layer can be designed into process flow to form the fuse, the preferred structure is to use the existing process layers as the fuse material in order to reduce cost. The most commonly used fuse materials are poly-silicon layer and metal layer. The fuse can be cut open by electrical means such as an electrical pulse, or by laser.

A poly-silicon material is used as the fuse itself. The electrical connections to either end of the fuse are made with metal layer through contacts. There is no other metal or poly-silicon layer on top of the fuse. There is a window etched open on the passivation layer above the fuse to allow better penetration of the laser. The substrate below the fuse can be either field oxide with P-well substrate or field oxide with N-well.

In a process that has multiple layers of passivation, there can be a thin layer of passivation layer on top of the fuse to prevent oxidation and moisture penetration.

The present invention provides at least the following advantages:

A simple fuse structure has been implemented using the existing standard CMOS process layers without adding to the process complexity.

The fuse is applied as an integrated on-chip memory element in the CMOS image sensor circuit to record the address information of the bad pixels. The application of an integrated memory element on the same chip eliminates the need for external memory and therefore reduces the cost and overall component count of the camera module.

The dynamic readout circuit of the fuse array reduces the data delay and increases the operating frequency of the circuit.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings, FIG. 1 is a circuit diagram implementing a fuse as the memory element according to an embodiment of the present invention;

FIG. 2A is a diagram illustrating a fuse structure in a CMOS process flow according to an embodiment of the present invention; and

FIG. 2B is a diagram illustrating a fuse structure in a CMOS process flow according to an embodiment of the present invention.

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

Therefore, the present invention provides a fuse structure and application thereof for a CMOS sensor that implements a fuse structure and a dynamic readout circuit, which are designed as an integrated part of the CMOS image sensor in standard CMOS process.

The main circuit block of an image sensor circuit is the image sensor array, consisting of an array of identical sensor pixels, each of which converts the incident light energy into a corresponding electrical signal. A lens or a set of lenses are typically used to project and focus the image from the surrounding scenery onto the sensor array. Because the image projected on the sensor array typically contain different variations in light intensity and color spectrum, each sensor pixel in the array produces different output signals depending on the particular portion of the image that is projected onto that pixel. The electrical outputs from the pixels are sensed, or read out, in a predetermine sequence. Based on the data readout from the pixels and the sequence of signal readout, one can reconstruct the image that is projected onto the sensor array. The output data from each pixel in the sensor array contributes to the overall reconstructed image.

However, if one or more pixels produce erratic output signals that do not correspond to the individual incident light, the reconstructed image can suffer degradation in image quality. The pixels that produce erratic output signals are considered bad pixels. One example of a bad pixel is a “dead” pixel, which produces a zero signal regardless of the incident light condition. Another example of a bad pixel is a “hot” pixel, which produces a high output signal even if there is no incident light. A dead pixel causes a black dot on the reconstructed image, while a hot pixel causes a bright dot on the reconstructed image. Since a bad pixel cannot respond to the incident light in a predetermined way, the image data corresponding to the bad pixel output is therefore not available.

When a sensor array is built in any integrated circuit process, due to a variety of defect mechanisms there is a finite probability that any given pixel can be bad. As a result, the probability of finding a sensor array containing no bad pixel decreases rapidly as the sensor array size increases.

However, if the output data from the bad pixel can be corrected to a certain degree, even though not fully corrected, it can be deemed useful enough not to reject the sensor, thus increasing the yield rate of the process.

There are many methods of performing the correction, the simplest one being a linear interpolation between the neighboring pixel outputs. On the other hand, before any correction can be done it is necessary to know which pixel needs to be corrected, which requires some kind of memory element to record the coordinates, or addresses, of the bad pixels. External off-chip memories, a ROM, for example can be used to record the addresses. The approach will require an additional memory chip that occupies area on the PC board, increases overall power dissipation, and complicates the system design. An on-chip memory element is therefore desired to eliminate the above problems associated with external memories. Furthermore, it is preferred that the memory element is able to store the bad pixel addresses indefinitely. In most standard CMOS logic process there is no memory element available that can store information indefinitely. A memory element must be created with minimal change to the process flow.

Fuses of poly-silicon or metal composition, or variations of such, can be used as the memory element in any of the existing standard CMOS process for use in the CMOS image sensor application to record the appropriate information. Such information includes, but not limited to the bad pixel addresses for use later on to correct the bad pixel outputs.

Refer to FIG. 1 which is a circuit diagram implementing a fuse as the memory element according to an embodiment of the present invention.

FIG. 1 only shows one bit output. However, extension of the circuit to multiple bit output is straightforward. The circuit operation is described next.

This embodiment shows a memory array that is composed of m banks of memory elements 5. Each bank contains n memory elements. Each memory element consists of a fuse 10 and a select pass transistor 20. The inverters 30 shown (INVO to INVm-1) are tri-state inverters enabled by the enable signal. An address decoder, not shown in the figure, is used to decode the memory address input bits to turn on the proper selection signals (Sel0 to Seln-1) and enable signals (en0 to enm-1). Only one of the selection signals and one of the enable signals are allowed to turn on. Each memory element therefore has a unique address (i,j), where 0<=i,=m-1 and 0<=j<=n-1.

To store the information, the proper fuses must be cut by some means. The data readout operation consists of two phases. The first phase is the precharge phase, during which the precharge signal 40 is turned high to turn on the precharge NMOS transistor. The nodes node0 through nodem-1 are therefore precharged to ground. The precharge signal 40 is turned low to turn off the precharge transistors at the end of the precharge phase.

The second phase is the readout phase, during which the proper selection and enable signals are turned on to allow the data stored in the selected memory element 5 to be transmitted to the output. Assuming memory element (i,j) is selected and the fuse in that element is not cut, the node nodei will be allowed to charge up to VDD through the fuse and pass transistor. Since the tri-state inverter INVi is enabled by the decoder output, the output Dout 50 will be logic 0. If the fuse in the selected memory element is cut, the node nodei will remain low and the output Dout 50 will be logic 1.

Dividing the memory array into separate banks separated by the tri-state drivers has the advantage of reducing the parasitic capacitance that the memory element 5 has to drive, therefore reducing the rise/fall time and effectively increases the readout speed. The idea can be readily applied to more than two levels of division.

Although a dedicated layer can be designed into process flow to form the fuse, the preferred structure is to use the existing process layers as the fuse material in order to reduce cost. The most commonly used fuse materials are poly-silicon layer and metal layer. The fuse can be cut open by electrical means such as an electrical pulse, or by laser.

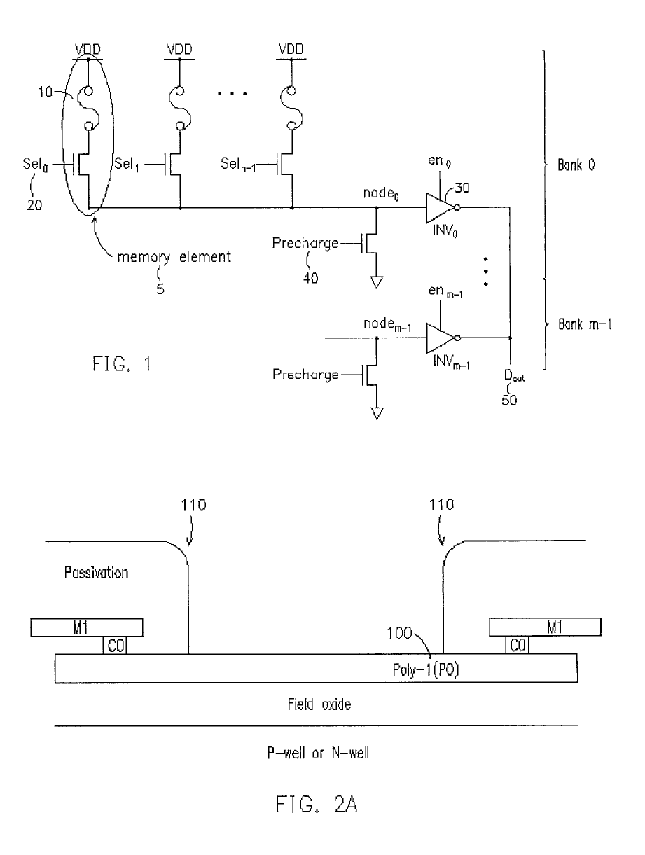

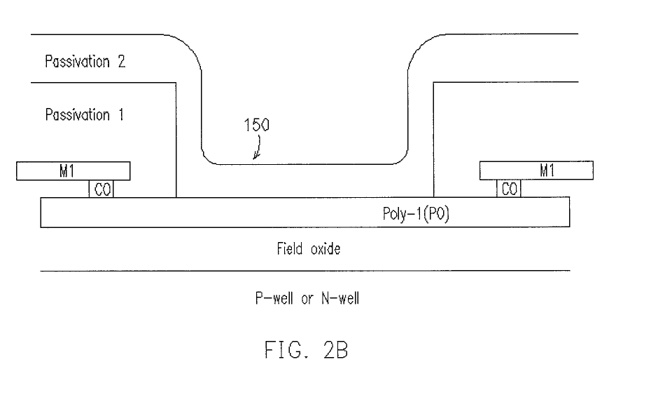

Refer to FIG. 2A, which is a diagram illustrating a fuse structure in a CMOS process flow according to an embodiment of the present invention.

In FIG. 2A, a poly-silicon material 100 is used as the fuse itself. The electrical connections to either end of the fuse are made with metal layer through contacts. There is no other metal or poly-silicon layer on top of the fuse. There is a window etched open on the passivation layer 110 above the fuse to allow better penetration of the laser. The substrate below the fuse can be either field oxide with P-well substrate or field oxide with N-well.

Refer to FIG. 2B, which is a diagram illustrating a fuse structure in a CMOS process flow according to an embodiment of the present invention.

In a process that has multiple layers of passivation, there can be a thin layer of passivation layer 150 on top of the fuse to prevent oxidation and moisture penetration.

The present invention provides at least the following advantages:

A simple fuse structure has been implemented using the existing standard CMOS process layers without adding to the process complexity.

The fuse is applied as an integrated on-chip memory element in the CMOS image sensor circuit to record the address information of the bad pixels. The application of integrated memory element on the same chip eliminates the need for external memory and therefore reduces the cost and overall component count of the camera module.

The dynamic readout circuit of the fuse array reduces the data delay and increases the operating frequency of the circuit.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A CMOS image sensor comprising:
a fuse structure; and
a dynamic readout circuit;
wherein the fuse structure and the dynamic readout circuit are designed and implemented as an integrated part of the CMOS image sensor.

2. The CMOS image sensor of claim 1, wherein the fuse structure stores bad pixel addresses.

3. The CMOS image sensor of claim 1, wherein the fuse structure records addresses of dead pixels which produce a zero signal regardless of incident light condition.

4. The CMOS image sensor of claim 1, wherein the fuse structure records addresses of hot pixels which produce a high output signal even if there is no incident light.

5. The CMOS image sensor of claim 1, wherein the memory element is able to store information non-volatilely.

6. The CMOS image sensor of claim 1, wherein the fuse structure is of poly-silicon or metal composition.

7. The CMOS image sensor of claim 1, wherein the memory element stores information comprising bad pixel addresses for use to correct bad pixel output.

8. A CMOS image sensor comprising:
a fuse structure used as a memory element; and
a dynamic readout circuit for selecting and enabling signals to allow data stored in the memory element to be output;
wherein the fuse structure and the dynamic readout circuit are designed and implemented as an integrated part of the CMOS image sensor.

9. The CMOS image sensor of claim 8, wherein the fuse structure stores bad pixel addresses.

10. The CMOS image sensor of claim 8, wherein the fuse structure records addresses of dead pixels which produce a zero signal regardless of incident light condition.

11. The CMOS image sensor of claim 8, wherein the fuse structure records addresses of hot pixels which produce a high output signal even if there is no incident light.

12. The CMOS image sensor of claim 8, wherein the memory element is able to store information non-volatilely.

13. The CMOS image sensor of claim 8, wherein the fuse structure is of poly-silicon or metal composition.

14. The CMOS image sensor of claim 8, wherein the memory element stores information comprising bad pixel addresses for use to correct bad pixel output.

15. A CMOS image sensor comprising a fuse structure and a dynamic readout circuit implemented as an integrated part of the CMOS image sensor.

16. An image sensor comprising:
an image sensor array comprising an array of sensor pixels, which convert incident light energy into a corresponding electrical signal;
at least one lens for projecting and focusing an image onto the image sensor array;
a fuse structure for recording information; and
a dynamic readout circuit for outputting data stored in the fuse structure.

17. The CMOS image sensor of claim 16, wherein the fuse structure stores bad pixel addresses.

18. The CMOS image sensor of claim 16, wherein the fuse structure records addresses of dead pixels which produce a zero signal regardless of incident light condition.

19. The CMOS image sensor of claim 16, wherein the fuse structure records addresses of hot pixels which produce a high output signal even if there is no incident light.

20. The CMOS image sensor of claim 16, wherein the memory element is able to store information non-volatilely.

21. The CMOS image sensor of claim 16, wherein the fuse structure is of polysilicon or metal composition.

22. The CMOS image sensor of claim 16, wherein the memory element stores information comprising bad pixel addresses for use to correct bad pixel output.
